(19) United States
(12) Patent Application Publication
(10) Pub. No.: US 2024/0112973 A1
(43) Pub. Date: Apr. 4, 2024

(54) METHODS AND APPARATUSES FOR THROUGH-GLASS VIAS

(71) Applicant: Intel Corporation, Santa Clara, CA (US)

(72) Inventors: Jeremy D. Ecton, Gilbert, AZ (US); Gang Duan, Chandler, AZ (US); Brandon Christian Marin, Gilbert, AZ (US); Suddhasattwa Nad, Chandler, AZ (US); Srinivas V. Pietambaram, Chandler, AZ (US)

(73) Assignee: Intel Corporation, Santa Clara, CA (US)

(21) Appl. No.: 17/958,053

(22) Filed: Sep. 30, 2022

(51) Int. Cl. H01L 23/15; H01L 21/48; H01L 23/498

(52) U.S. Cl. CPC H01L 23/15; H01L 21/486; H01L 23/49827

(57) ABSTRACT

Through-glass vias (TGVs) are formed without the use of a planarization step to planarize the TGV fill material after filling holes that extend through a glass layer with the fill material. After the holes are filled with the fill material, the fill material is etched and the glass layer is etched. After etching of the glass is performed, the top and bottom surfaces of the glass layer are recessed relative to the top and bottom surfaces of the fill material in the holes, resulting in formation of fill material stubs. TGV pads are then formed on the fill material stubs. The resulting pads can have protrusions that extend away from a surface of the glass layer. If the TGVs are plated through-holes, a portion of the metal lining the inner wall of a TGV hole can extend past a surface of the glass layer and into a TGV pad.

### BACKGROUND

Integrated circuit die partitioning can aid in meeting the demand for increased levels of integration in high performance computing devices and device form factor miniaturization. In turn, die partitioning can drive demand for fine-pitch die-to-die interconnections. These interconnections can be integrated in a physical substrate to which integrated circuit dies are attached.

### BRIEF DESCRIPTION OF THE DRAWINGS

FIGS. 1A-1C illustrate a simplified version of a process flow resulting in through-glass vias with recesses.

FIGS. 2A-2C are cross-sectional views of an example glass core comprising through-glass vias without recesses.

FIGS. 3A-3D illustrate a simplified process flow of fabricating recess-free through-glass vias.

FIG. 4 is a simplified cross-sectional view of an example portion of a substrate of an integrated circuit component, the substrate comprising a glass core.

FIG. 5 is an example method of forming a through-glass via.

FIG. 6 is a top view of a wafer and dies that may be included in a microelectronic assembly, in accordance with any of the embodiments disclosed herein.

FIG. 7 is a cross-sectional side view of an integrated circuit device that may be included in a microelectronic assembly, in accordance with any of the embodiments disclosed herein.

FIG. 8 is a cross-sectional side view of an integrated circuit device assembly that may include a microelectronic assembly, in accordance with any of the embodiments disclosed herein.

FIG. 9 is a block diagram of an example electrical device that may include a microelectronic assembly, in accordance with any of the embodiments disclosed herein.

### DETAILED DESCRIPTION

The demand for the miniaturization of computing device form factors and increased levels of integration to achieve high performance in computing devices is helping drive the development of sophisticated packaging approaches in the semiconductor industry. Die partitioning, in which a desired functionality is implemented by multiple interconnected smaller integrated circuit dies can help enable form factor miniaturization and high performance, without the yield issues associated with implementing the desired functionality with a single larger integrated circuit die. However, die-to-die interconnections having a fine pitch are needed to realize the full potential of die partitioning. One 2.5D packaging approach to enable high-density interconnects between heterogeneous dies on a single package employs small silicon bridge chips embedded in the package, which enables the placement of high density die-to-die connections only where needed. Standard flip-chip assembly is used for power delivery and to connect high-speed signals directly from integrated circuit dies to the package substrate. This can be a simpler and lower cost 2.5D packaging approach than an expensive silicon interposer with through silicon vias (TSVs). One embodiment of this bridge-based interconnection approach is Intel®'s Embedded Multi-die Interconnect Bridge (EMIB) technology.

For future generations of die partitioning, bridges that can connect dies at bump pitches of 25 microns or less are expected to be needed. Some existing approaches of using silicon bridge chips embedded in a 2.5D packaging approach can suffer from a high cumulative variation in the thickness of the bumps employed for attaching dies to a substrate, which can cause yield issues. As the number of embedded bridges in a package substrate increases as more complex die partitioning schemes are desired, the cost of embedding the bridges can increase and yields may suffer. Alternate architectures and/or approaches have been proposed, such as stacking integrated circuit dies vertically (e.g., Intel®'s Foveros technology being one example) or using silicon bridges with embedded functional integrated circuit dies and/or through-silicon vias.

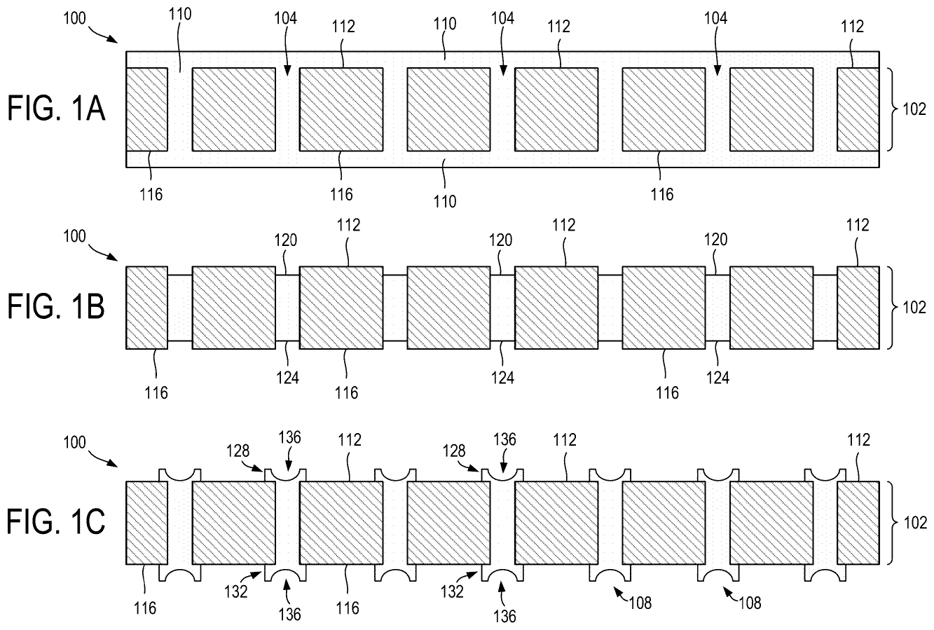

Another option for enabling fine die-to-die interconnections is incorporating a thin glass core into the substrate package. As compared to a conventional epoxy core a glass core offers several advantages including a higher plated through hole density, lower signal loss, and lower total thickness variation. In some existing process flows for incorporating a glass core in a package substrate, a planarization step (e.g., a copper chemical mechanical planarization (CMP) step) is used during fabrication of through-glass vias (TGVs) to make the copper flush with the glass core. The expense of this planarization step can drive up the cost of implementing such process flows. Approaches to eliminating the copper planarization step are being explored, but some result in a significant recess in the through-glass via, which can be a reliability risk (e.g., as a potential source of cracks), as illustrated in FIGS. 1A-1C.

FIGS. 1A-1C illustrate a simplified version of a process flow resulting in through-glass vias with recesses. FIG. 1A illustrates a structure 100 (that will become a glass core that can be utilized in an integrated circuit component package substrate) comprising a layer of glass 102 in which holes 104 have been created and filled with a fill material 110 (e.g., copper). Layers of fill material have further been formed on an upper surface 112 and a bottom surface 116 of the layer of glass 102. FIG. 1B illustrates the structure 100 after etching of the fill material 110 to a point where top surfaces 120 and bottom surfaces 124 of the fill material 110 are recessed relative to the top and bottom surfaces 112 and 116 of the layer of glass 102. FIG. 1C illustrates the structure 100 after formation of a patterned layer of fill material to form top pads 128 and bottom pads 132 for the resulting through-glass vias 108. Due to the top and bottom fill material surfaces 120 and 124 being recessed relative to the top and bottom surfaces 112 and 116 of the layer of glass 102, the top and bottom pads 128 and 132 can comprise recesses 136 after formation of the pads 128 and 132.

Disclosed herein are technologies that do not use a planarization step, such as a copper CMP step, to produce through-glass vias and that produce through-glass vias that are free of recesses. After formation of holes that extend through the layer of glass in a glass core, the holes are filled with fill material (e.g., copper) and layers of the fill material are further formed on the top and bottom surfaces of the layer of glass. The fill material is then etched such that a surface of the fill material in the holes is recessed relative to the top and bottom surfaces of the layer of glass. The layer of glass is then etched (via a glass “etch-back” step) such that the top and bottom surfaces of the layer of glass are recessed relative to top and bottom surfaces of the fill material. Through-glass via pads are then formed on the top and bottom surfaces of the fill material. The resulting pads are recess free and can have protrusions that are coaxial with the holes in the layer of the glass occupied by the through-glass vias. Protrusions in through-glass via pads can present less of a reliability risk than recesses in the through-glass via pads when redistribution layers (RDLs) (or build-up layers, dielectric layers) are formed on a glass core. If a through-glass via is a plated through-glass via, a portion of the metal layer that lines the inner wall of the through-glass via hole can extend beyond the top or bottom surface of the layer of glass and into a pad.

Example embodiments will hereinafter be described in conjunction with the following drawing figures, wherein like numerals denote like elements. Figures are not necessarily to scale but may be relied on for spatial orientation and relative positioning of features. As may be appreciated, certain terminology, such as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

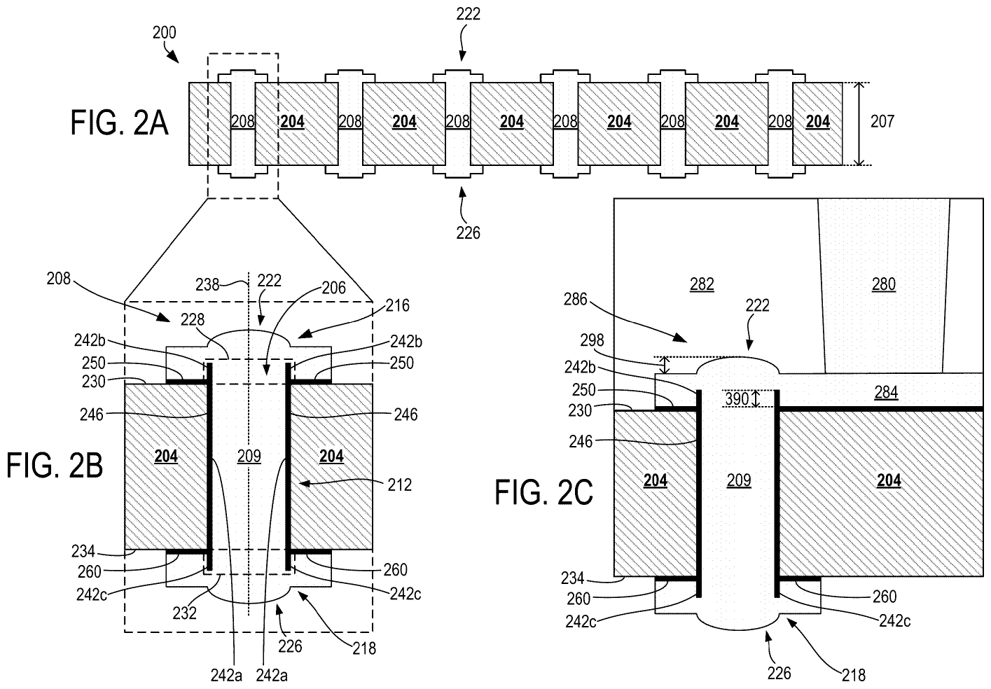

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components. For example, with reference to FIG. 2B, the top pad 216 is located on the top surface 230 of the layer of glass 204 with an intervening metal layer 250 between them, and the fill material 209 in the TGV body 212 is located on an inner wall 246 of the hole 206 with a portion of an intervening metal layer 242a between them.

Terms modified by the word “substantially” include arrangements, orientations, spacings, or positions that vary slightly from the meaning of the unmodified term. For example, the portion of a first layer or feature that is substantially perpendicular to a second layer or feature can include a first layer or feature that is +/−20 degrees from a second layer or feature, a first surface that is substantially parallel to a second surface can include a first surface that is within several degrees of parallel from the second surface. The amount of variation covered by a term modified by the term “substantially” is indicated throughout for certain arrangements, orientations, spacing, positions, etc. Values modified by the word “about” include values with +1-10% of the described values and values listed as being within a range include those within a range from 10% less than the described lower range limit and 10% greater than the described higher range limit.

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims

FIGS. 2A-2B are cross-sectional views of an example glass core comprising through-glass vias without recesses. FIG. 2A illustrates a glass core 200 comprising a layer of glass 204 and a series of plated through-glass vias 208. FIG. 2B illustrates a detailed cross-sectional view of one of through-glass vias 208. The plated through-glass vias 208 can be fabricated according to any of the semiconductor manufacturing process flows described herein. A through-glass via 208 comprises a via body (or pillar) 212 that extends through a hole 206 in the layer of glass 204 from a top surface 230 of the layer of glass 204 to a bottom surface 234 of the layer of glass 204, a top pad 216, and a bottom pad 218. A portion of the top pad 216 is located on the top surface 230 of the layer of glass 204 and a portion of the bottom pad 218 is located on the bottom surface 234 on the layer of glass 204. The via body 212, top pad 216, and bottom pad 218 comprise a fill material, such as copper, liquid metal, or another suitable metal or alloy. In some embodiments where the fill material is liquid metal, the liquid metal comprises gallium or an alloy of gallium, such as, for example, alloys of gallium and indium, eutectic alloys of gallium, indium, and tin, and eutectic alloys of gallium, indium, and zinc. In other embodiments, the fill material can comprise other liquid metals that are liquid at normal operating temperatures of a substrate comprising a glass core.

The top and bottom pads 216 and 218 comprise protrusions or bumps 222 and 226, respectively. As will be discussed in greater detail below, the protrusion 222 results from formation of the top pad 216 on a fill material stub 228 protruding from the top surface 230 of the layer of glass 204, and the protrusion 226 results from formation of the bottom pad 218 on a fill stub 232 protruding from the bottom surface 234 of the layer of glass 204. The stubs 228 and 232 are formed as a result of etching the layer of glass 204 after hole 206 has been at least partially filled with the fill material and the top and bottom surfaces of the layer of glass have been filled and plated with the fill material and the fill material has been subjected to an etch. As such, the protrusions 222 and 226 are coaxial with the hole 206. That is, the protrusions 222 and 226 and the hole 206 have a common axis 238. The protrusions 222 and 226 can be dome-shaped (as illustrated in FIG. 2B), rectangular-shaped (as illustrated in FIG. 2A), or any other shape.

In some embodiments, the through-glass vias disclosed herein, such as through-glass via 208 are plated through-glass vias. That is, the layer of glass 204 is lined with a thin layer of metal (plating layer or plating metal) prior to the through-glass via hole being filed by the fill material and the layers of fill material being formed on the top and bottom surfaces of the layer of glass. The thin layers of metal can promote adhesion of the fill material (by, for example, acting as a seed layer) to the glass layer. The plated through-glass via 208 illustrated in FIG. 2B comprises a first metal layer 242, a first portion 242a of which is positioned adjacent to an inner wall 246 of the through-glass via hole, a second metal layer 250 positioned adjacent to the top surface 230 of the layer of glass 204, and a third metal layer 260 positioned adjacent to the bottom surface 234 of the layer of glass 204. The first metal layer 242 further comprises a second portion 242b that extends past the top surface 230 of the layer of glass 204 and into the top pad 216 and a third portion 242c that extends past the bottom surface 234 of the layer of glass 204 and into the bottom pad 218. As will be discussed in greater detail below, the portions of the first metal layer 242 (second and third portions 242b and 242c) that extend past the top and bottom surfaces 230 and 234 of the layer of glass 204 are a result of etching the layer of glass 204 after filling the hole 206 with the fill material. The metal layers 242, 250, and 260 can comprise ruthenium, titanium, or another suitable metal. In some embodiments, the through-glass vias disclosed herein are not plated through-holes and thus do not comprise metal layers (e.g., layers 242, 250, 260).

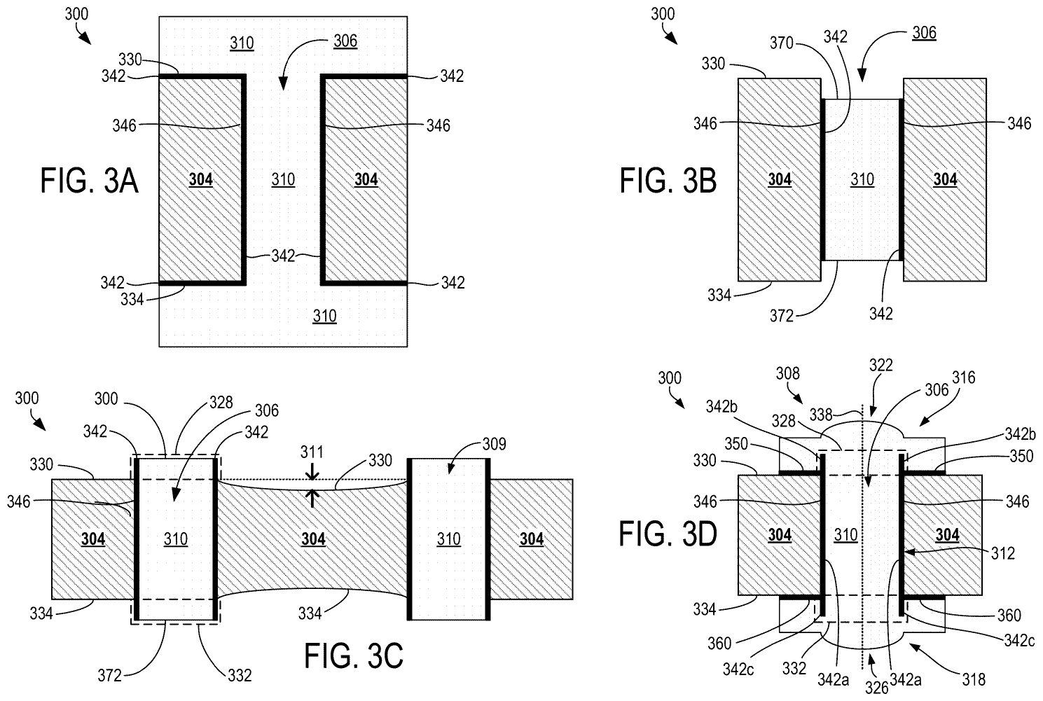

The features of any of the through-glass vias described herein can have the following dimensions. In some embodiments, the thickness of the metal layers (e.g., 242, 250, 260, 342, 350, 360) can be less than one micron. In other embodiments, the thickness of these metal layers can be less than 500 nanometers. In some embodiments, the thickness of the pads (e.g., 216, 218, 284, 316, 318), excluding any protrusion, can be in the range of 5-70 microns. In other embodiments, the thickness of the pads can be in the range of 5-25 microns. In some embodiments, the height of the protrusions (e.g., 222, 226, 322, 326) can be in the range of 1-20 microns. The protrusion height is measured as indicated in FIG. 2C (e.g., the height of protrusion 222 is height 298). In some embodiments, the thickness of the glass core (e.g., thickness 207 of glass core 204) is in the range of 200-600 microns. In some embodiments, the thickness of the glass core is in the range of 50 microns-2 millimeters. In some embodiments, the portion of the metal layer extending into a pad can extend into the pad a distance within the range of 1-20 microns (e.g., distance 390 in FIG. 3D).

The glass used in any of the glass cores described or referenced herein can be an alkali-free alkaline earth boro-aluminosicilate glass, such as a glass comprising aluminum, oxygen, boron, silicon, and an alkaline-earth metal (e.g., beryllium, magnesium, calcium, strontium, barium, radium, such as a glass comprising SiO₂, Al₂O₃, B₂O₃, and MgO), or a photosensitive glass (photomachineable or photostructurable glass). In some embodiments, a photosensitive glass can be a glass that belongs to the lithium-silicate family of glass (e.g., a glass comprising lithium, silicon, and oxygen) comprising metallic particles (which can be referred to as a glass layer metal), such as gold, silver, or other suitable metallic particles. A glass core may comprise multiple glass layers. For example, in some embodiments, a glass core 200 can comprise multiple layers of glass 204 and a through-glass via can extend through the multiple layers of glass.

In some embodiments, protrusions of the through-glass vias disclosed herein may not be distinguishable in an analytic cross-section (e.g., cross-sections generated by transmission electron microscopy (TEM), scanning electron microscopic (SEM), etc. analytical tools) when a via of a first redistribution layer (a “V0” via of a first RDL) is aligned or overlaps with the hole of through-glass via. This is because a V0 via may comprise the same material as the fill material (e.g., copper) that comprises the pad of the through-glass via and it may not be possible to tell where the protrusion of through-glass via ends and a V0 via begins.

FIG. 2C illustrates a first-level via connecting to an example through-glass via comprising protrusions in which the via is laterally offset from the through-glass via. A first-level via (e.g., a “V0” via) 280 is formed in a dielectric layer 282 and contacts to a top pad 284 of a through-glass via 286. The through-glass via 286 is a variation of the through-glass via 208 illustrated in FIGS. 2B, but with the top pad 284 extended in one lateral direction as compared to the top pad 216 of FIG. 2B. Due to the via 280 being laterally offset from the through-glass via 286, the protrusion 222 would be distinguishable in an analytical cross-section.

FIGS. 3A-3D illustrate a simplified process flow of fabricating recess-free through-glass vias. FIG. 3A illustrates a structure 300 comprising a layer of glass 304 in which a hole 306 that extends through the layer of glass 304 has been formed. A metal layer 342 has been formed on an inner wall 346 of the hole 306, a top surface 330 and a bottom surface 334 of the layer of glass 304. The metal layer 342 can comprise a metal, which can be ruthenium, titanium, or other suitable metal. The hole 306 has been at least partially filled with a fill material 310 (such as copper, liquid metal, or another suitable metal or alloy), and layers of fill material 310 have been formed on the top and bottom surfaces 330 and 334. The metal layer 342 is positioned between the layer of glass 304 and the fill material 310.

FIG. 3B illustrates the structure 300 after etching the fill material 310 to remove the fill material and metal layers from the top and bottom surfaces 330 and 334. The fill material etch can be referred to as a “bulk etch,” or a “bulk copper etch” in embodiments where the fill material is copper. The fill material etch further removes a portion of the fill material 310 and the metal layer 342 in the hole 306, leaving a top surface 370 and a bottom surface 372 of the fill material 310 and the metal layer 342 in the hole recessed relative to the top and bottom surfaces 330 and 334 of the layer of glass 304.

FIG. 3C illustrates the structure 300 after an etch of the layer of glass 304. This process step can be referred to as a glass “etch-back” step. The etching of the glass results in the top and bottom surfaces 330 and 334 of the glass layer, respectively, being recessed relative to the top and bottom surfaces 370 and 372 of the fill material 310 and the metal layer 342. Fill material and metal layer stubs 328 and 332 protrude from the top and bottom surfaces 330 and 334, respectively, of the layer of glass 304. In some embodiments, a glass etch-back step may result in dishing or scalloping of the top or bottom surfaces 330 or 334 of the structure 300 between adjacent through-glass vias. That is, for a dished layer of glass, there can be more etching of the layer of glass at points further away from adjacent through-glass vias than at points closer to the adjacent through-glass vias. FIG. 3C illustrates dished top and bottom surfaces 330 and 334 between the hole 306 and an adjacent hole 309 in the layer of glass 304 filled by fill material 310 that will form a second through-glass via. In embodiments where the glass etch-back step is preceded by a planarization of the fill material (e.g., copper CMP planarization), the depth of the dishing (depth 311) can be in the range of 0.25-10 microns. In embodiments where the glass etch-back step is preceded by a bulk copper etch, the depth of the dishing can be 30 microns or less. In a scalloped surface of the layer of glass, multiple dishes are present in the surface between adjacent through-glass vias.

FIG. 3D illustrates the structure 300 after formation of a metal layer 350 on the top surface 330 of the layer of glass 304 and a metal layer 360 on the bottom surface 334 of the layer of glass 304, formation of a patterned layer (through-glass via pad) 316 of fill material 310 on the stub 328, and formation of a patterned layer (through-glass via pad) 318 on the stub 332. The pads 316 and 318 comprise the fill material 310. The metal layers 350 and 360 and pads 316 and 318 are formed via a photolithography process by which the metal layers 350 and 360 and pads 316 and 318 are selectively formed on the structure 300. The metal layers 350 and 360 comprise a metal, such as ruthenium, titanium, or another suitable metal. A through-glass via 308 comprises the top pad 316, the bottom pad 318, and a through-glass via body (or pillar) 312 that comprises the fill material 310 occupying the hole 306.

As a result of the pads 316 and 318 being formed on top of the fill material stubs 328 and 332, the pads 316 and 318 are recess-free and comprise protrusions 322 and 326, respectively. The protrusions 322 and 326 extend away from the surface of the top and bottom surfaces 330 and 334, respectively, of the layer of glass 304 and are coaxial with the hole 306 about an axis 338. The protrusions can be domed-shaped (as illustrated in FIG. 3D) or any other shape. The metal layer 342 comprises a first portion 342a that is positioned adjacent to the inner wall 346 of the hole 306, a second portion 342b that extends past the top surface 330 of the layer of glass 304 and into the top pad 316, and a third portion 342c that extends past the bottom surface 334 of the layer of glass 304 and into the bottom pad 318. The layer of glass 304 can be made of any glass that is described or referenced herein as being part of a glass core (such as any of the glasses described above that can be used for the layer of glass 204).

Although FIGS. 3A-3D illustrate a process flow in which a glass etch-back process is used (and does not contain a fill material planarization step) in the fabrication of through-glass vias, the process flow can be extended to create recess-free vias that extend through dielectric layers other than glass, such as Ajinomoto Build-Up Film (ABF). Such process flows can utilize a dielectric etch-back processing step (which could be either a wet or dry etch step) that etches the dielectric to create fill material stubs that extend from a surface of the dielectric (e.g., stubs 328, 332) and that will be part of the thru-dielectric vias.

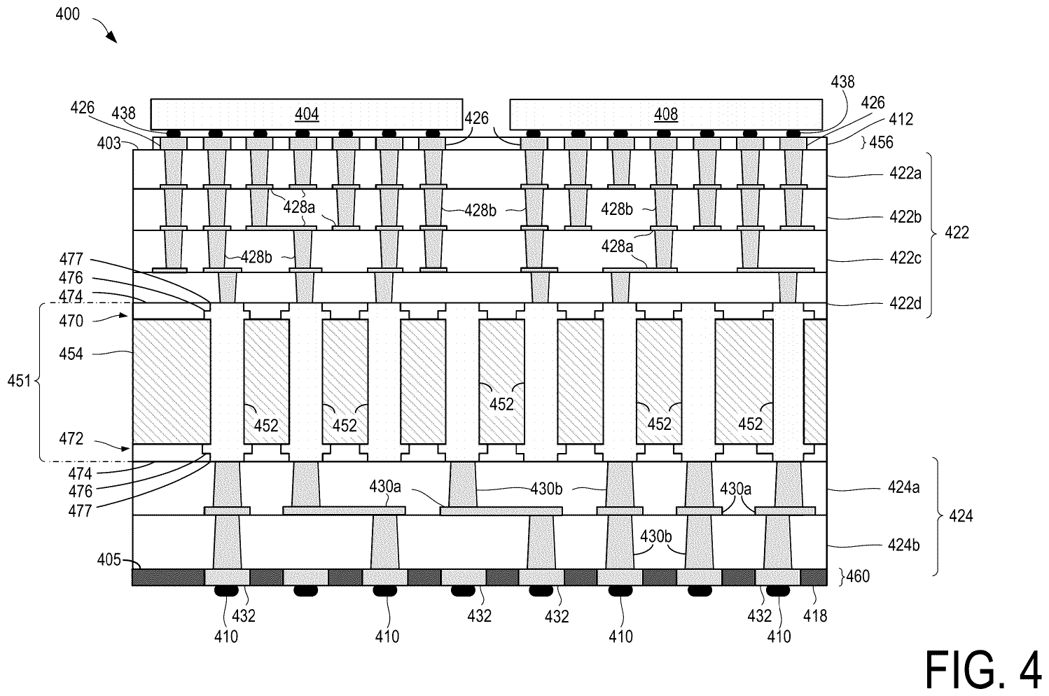

FIG. 4 is a simplified cross-sectional view of an example portion of a substrate of an integrated circuit component, the substrate comprising a glass core. The substrate portion 400 comprises a glass core 451 positioned between a first set of dielectric layers (or redistribution layers (RDLs) build-up layers) 422 (422a, 422b, 422c, 422d) and a second set of dielectric layers 424 (424a, 424b). The first set of dielectric layers 422 and the second set of the dielectric layers 424 are stacked vertically. That is, the individual first dielectric layers 422 (e.g., 422a) are positioned adjacent to another first dielectric layer 422 (e.g., 422b) and the individual second dielectric layers 424 (e.g., 424a) are positioned adjacent to another second dielectric layer 424 (e.g., 424b). The glass core 451 comprises a layer of glass 454, encapsulation layers 470 and 472, and through-glass vias 452 located in the layer of glass 454. The encapsulation layers 470 and 472 comprise dielectric layers 474 in which through-glass via pads 476 are located. The through-glass vias 452 are any of the through-glass vias disclosed herein that are formed without a fill material planarization step. The through-glass vias 452 comprise protrusions 477. The through-glass vias 452 can be plated through-glass vias and in such embodiments, the metal layer positioned adjacent to an inner wall of the hole in the layer of glass 454 through which a through-glass vias 452 extends, extends into a portion of the pads 476.

An upper surface contact layer 456 comprises a solder resist or other suitable dielectric material 412 and conductive contacts 426 arranged to correspond to the pinouts of dies 404 and 408 directly attached to substrate portion 400. The upper surface contact layer 456 (and hence, the conductive contacts 426) are located on a top dielectric layer (e.g., 422a) of the first dielectric layers 422. A lower surface contact layer 460 comprises a solder resist or other suitable dielectric material 418 and conductive contacts 432 are arranged to correspond to a desired package-level pinout. The lower surface contact layer 460 (and hence, the conductive contacts 432) is located on a bottom dielectric layer (e.g., 424b) of the second dielectric layers 424. Dielectric layers 422 comprise conductive traces (metal lines) 428a and vias 428b, and dielectric layers 424 comprise conductive traces 430a and vias 430b.

Integrated circuit dies 404 and 408 are attached to the substrate portion 400 at conductive contacts 426 via solder balls 438. In other embodiments, the dies 404 and 408 can be attached to the substrate portion 400 via other approaches, such as hybrid bonding. The substrate portion 400 further comprises solder balls 410 attached to conductive contacts 432. In other embodiments, the substrate portion 400 does not comprise solder balls 410 and the substrate portion 400 can attach to other components, such as a printed circuit board, via conductive contacts 432 that are pads.

In various embodiments, an RDL, dielectric, or build-up layer (e.g., layers 422a, 422b, 422c, 424a, 424b) comprises a dielectric material and may include a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, an RDL comprises a photo-imageable dielectric (PID). In some embodiments, an RDL comprises an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties of the RDLs (e.g., the dielectric constant (Dk), and/or dissipation factor (insertion loss) (Df)).

Although the figures illustrate four RDL layers 424 position above the glass core and two RDL 424 layers below the glass core, in practice, there can be any number of RDL layers in a substrate package. For example, in server applications, an integrated circuit component package can comprise up to RDL layers.

As used herein, “interconnect structures” can comprise one or more conductive traces, one or more vias, or a combination thereof. The term conductive trace can refer to via contacts, which can be metal lines to which vias connect and do not comprise a lateral signal routing portion. Interconnect structures can be present in various RDLs, dielectric layers, build-up layers, or glass layers, and can span multiple such layers. Interconnect structures may collectively provide an electrically conductive path from a feature on a first surface 403 of the substrate portion 400 to a feature on a second surface 405 of the substrate portion 400. In various embodiments, an interconnect structure in the first dielectric layer 422 is attached to an interconnect structure in the second dielectric layer 424 by a through-glass via 452, thereby providing an electrically conductive path through the package substrate portion 400. The conductive traces, via contacts, and vias can comprise an electrically conductive material such as a metal (e.g., copper, aluminum, nickel, cobalt, iron, tin, gold, silver, or combinations thereof.

An integrated circuit component comprising a substrate with a glass core comprising any of the through-glass vias described herein can be attached to a printed circuit board. In some embodiments, one or more additional integrated circuit components can be attached to the circuit board. In some embodiments, the printed circuit board and the integrated circuit component can be located in a computing device that comprises a housing that encloses the printed circuit board and the integrated circuit component.

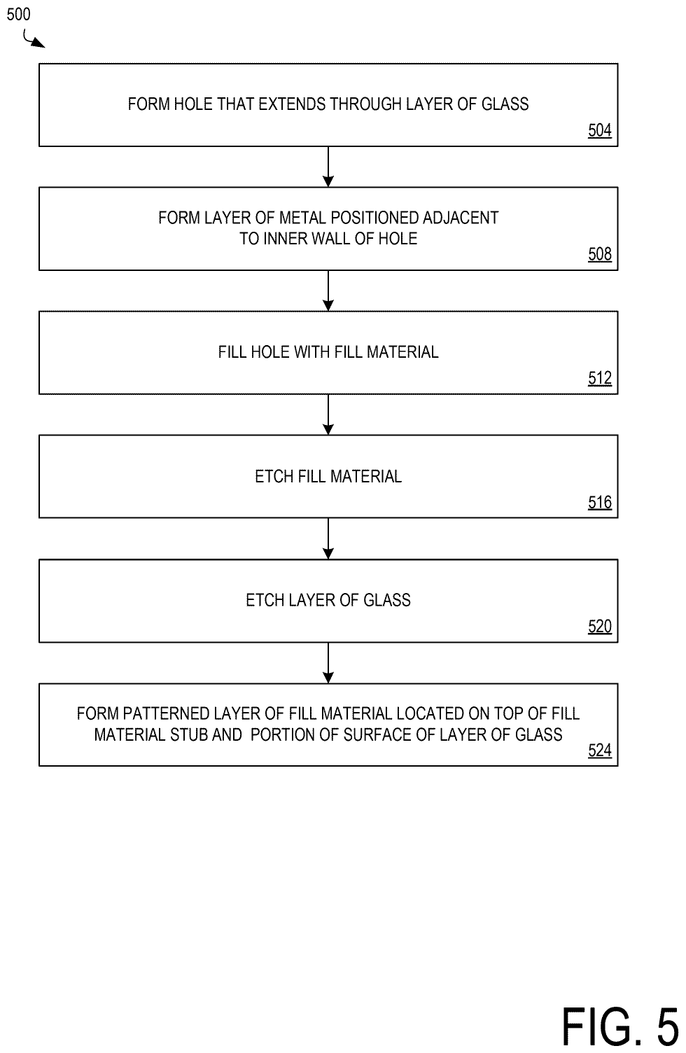

FIG. 5 is an example method of forming a through-glass via. The method 500 can be performed by, for example, an integrated circuit component manufacturer. At 504, a hole is formed that extends through a layer of glass. At 508, a metal layer positioned adjacent to an inner wall of the hole is formed. At 512, the hole is filled with a fill material, the metal layer positioned between the layer of glass and the fill material, the fill material comprising a metal. At 516, the fill material is etched to remove a portion of the fill material in the hole, wherein a surface of fill material in the hole is recessed relative to a surface of the layer of glass after etching the fill material. At 520, the layer of glass is etched, wherein the top surface of the layer of glass is recessed relative to the surface of the fill material after etching the layer of glass, a stub of the fill material extending from the surface of the layer of glass after etching the layer of glass. At 524, a patterned layer of fill material is formed, located on top of the stub and a portion of the surface of the layer of glass, wherein a first portion of the metal layer is positioned adjacent to the inner wall of the hole, a second portion of the metal layer extends past the surface of the glass layer and into the patterned layer of fill material.

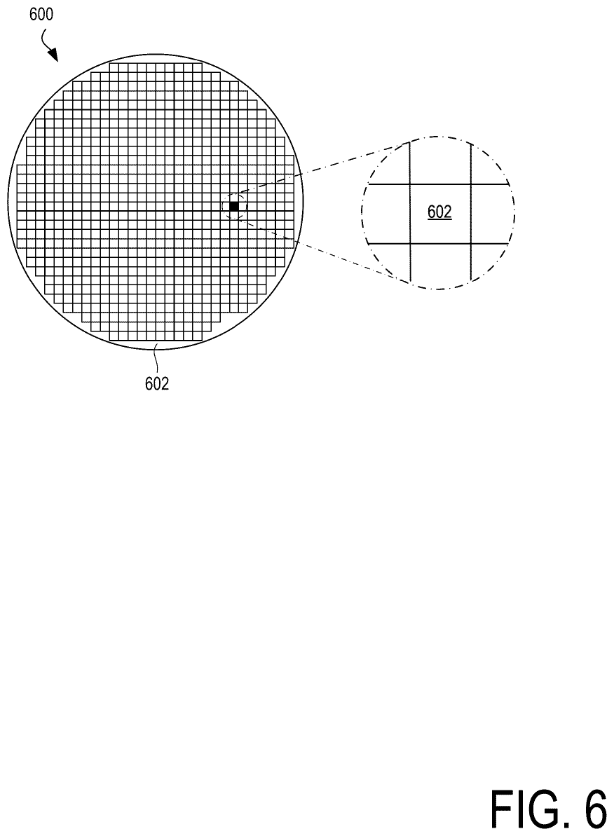

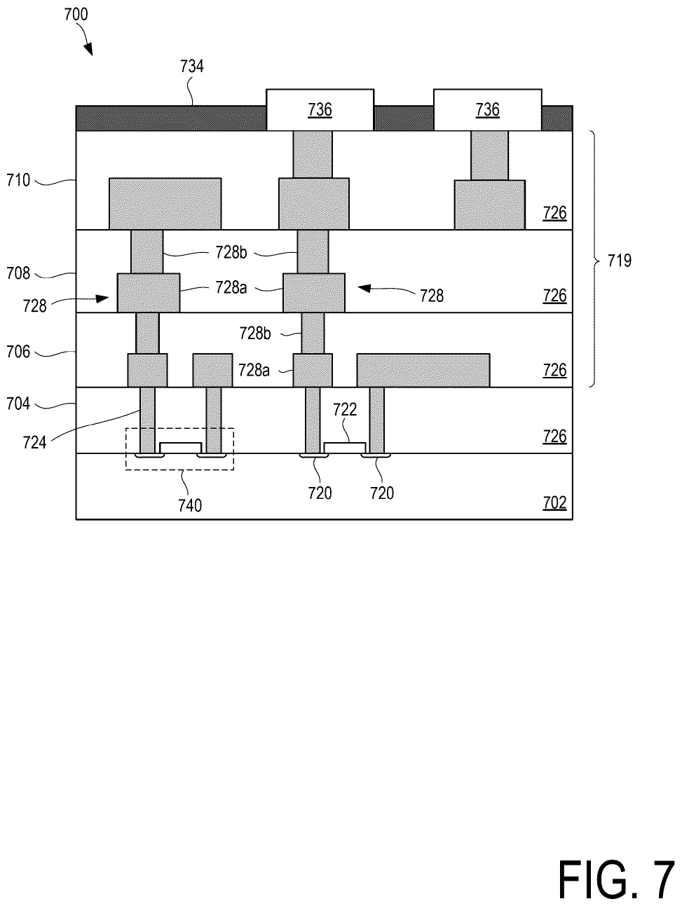

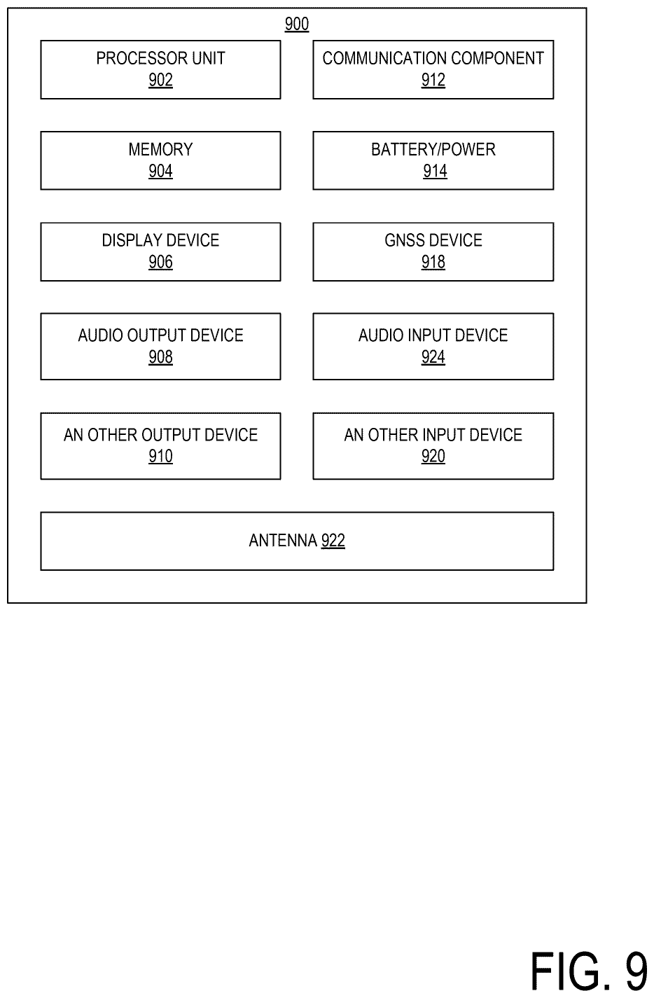

FIG. 6 is a top view of a wafer 600 and dies 602 that may be attached to any of the integrated circuit component package substrates or substrate portions disclosed herein (e.g., as any suitable ones of the dies 404, 408). The wafer 600 may be composed of semiconductor material and may include one or more dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may be any of the dies 400, 408 disclosed herein. The die 602 may include one or more transistors (e.g., some of the transistors 740 of FIG. 7, discussed below), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 902 of FIG. 9) or other logic that is configured to store information in the memory devices or execute instructions stored in the memory array. Various ones of the substrates disclosed herein may be manufactured using a die-to-wafer assembly technique in which some dies are attached to a wafer 600 that include other dies, and the wafer 600 is subsequently singulated.

FIG. 7 is a cross-sectional side view of an integrated circuit device 700 that may be included in any of the integrated circuit components disclosed herein. One or more of the integrated circuit devices 700 may be included in one or more dies 602 (FIG. 6). The integrated circuit device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit device 700 may be used. The die substrate 702 may be part of a singulated die (e.g., the dies 602 of FIG. 6) or a wafer (e.g., the wafer 600 of FIG. 6).

The integrated circuit device 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

A transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill material layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may consist of a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit device 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuit devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page from the perspective of FIG. 7. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit device 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit device 700 with another component (e.g., a printed circuit board). The integrated circuit device 700 may include additional or alternate structures to route the electrical signals from the interconnect layers 706-710; for example, the conductive contacts 736 may include other analogous features (e.g., posts) that route the electrical signals to external components. The conductive contacts 736 may serve as the conductive contacts 426, as appropriate.

In some embodiments in which the integrated circuit device 700 is a double-sided die, the integrated circuit device 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit device 700 from the conductive contacts 736. These additional conductive contacts may serve as the conductive contacts 432, as appropriate.

In other embodiments in which the integrated circuit device 700 is a double-sided die, the integrated circuit device 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit device 700 from the conductive contacts 736. In some embodiments, TSVs extending through the substrate can be used for routing power and ground signals from conductive contacts on the opposite side of the integrated circuit device 700 from the conductive contacts 736 to the transistors 740 and any other components integrated into the die 700, and the metallization stack 719 can be used to route I/O signals from the conductive contacts 736 to transistors 740 and any other components integrated into the die 700.

Multiple integrated circuit devices 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

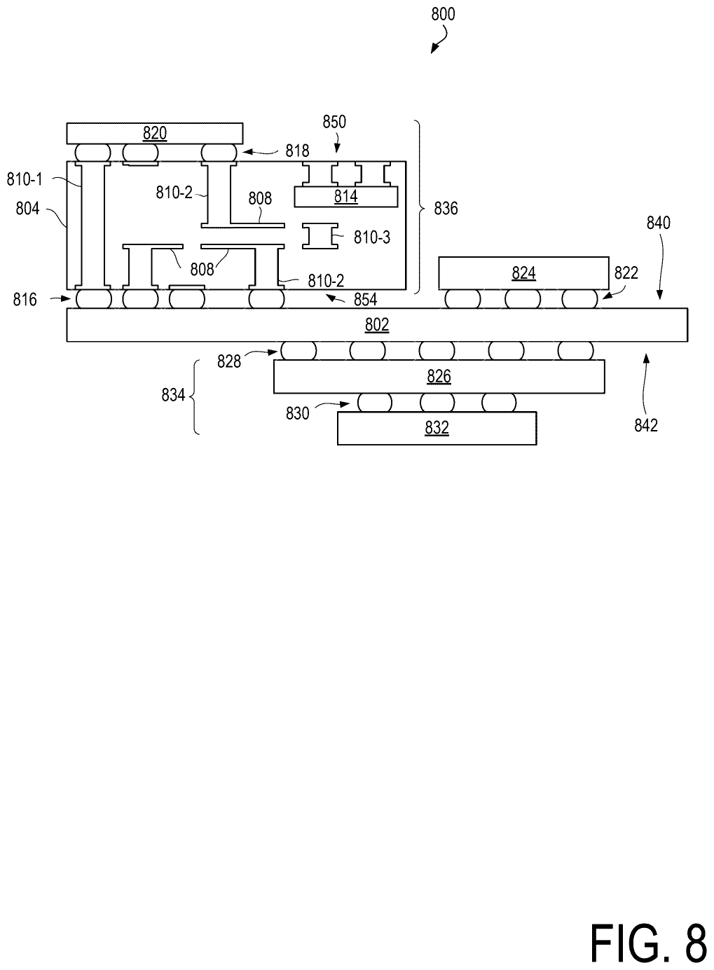

FIG. 8 is a cross-sectional side view of an integrated circuit device assembly 800 that may include any of the glass cores disclosed herein. In some embodiments, the integrated circuit device assembly 800 may be integrated circuit component package substrate that include substrate portion 400. The integrated circuit device assembly 800 includes a number of components disposed on a circuit board 802 (which may be a motherboard, system board, mainboard, etc.). The integrated circuit device assembly 800 includes components disposed on a first face 840 of the circuit board 802 and an opposing second face 842 of the circuit board 802; generally, components may be disposed on one or both faces 840 and 842. Any of the integrated circuit components discussed below with reference to the integrated circuit device assembly 800 may take the form of or comprise any suitable ones of the embodiments of an integrated circuit component package substrates or substrate portions described herein.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate. In some embodiments the circuit board 802 may be, for example, a printed circuit board attached to the bottom of any of the substrate or substrate portions disclosed herein. The integrated circuit device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 816 may serve as the coupling components illustrated or described for any of the substrate or substrate portion described herein, as appropriate.

The package-on-interposer structure 836 may include an integrated circuit component 820 coupled to an interposer 804 by coupling components 818. The coupling components 818 may take any suitable form for the application, such as the forms discussed above with reference to the coupling components 816. Although a single integrated circuit component 820 is shown in FIG. 8, multiple integrated circuit components may be coupled to the interposer 804; indeed, additional interposers may be coupled to the interposer 804. The interposer 804 may provide an intervening substrate used to bridge the circuit board 802 and the integrated circuit component 820.

The integrated circuit component 820 may be a packaged or unpacked integrated circuit product that includes one or more integrated circuit dies (e.g., the die 602 of FIG. 6, the integrated circuit device 700 of FIG. 7) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 820, a single monolithic integrated circuit die comprises solder bumps attached to contacts on the die. The solder bumps allow the die to be directly attached to the interposer 804. The integrated circuit component 820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 820 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 804 may spread connections to a wider pitch or reroute a connection to a different connection. For example, the interposer 804 may couple the integrated circuit component 820 to a set of ball grid array (BGA) conductive contacts of the coupling components 816 for coupling to the circuit board 802. In the embodiment illustrated in FIG. 8, the integrated circuit component 820 and the circuit board 802 are attached to opposing sides of the interposer 804; in other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through hole vias 810-1 (that extend from a first face 850 of the interposer 804 to a second face 854 of the interposer 804), blind vias 810-2 (that extend from the first or second faces 850 or 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art. In embodiments where the interposer is a non-printed circuit board

The integrated circuit device assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit device assembly 800 illustrated in FIG. 8 includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

FIG. 9 is a block diagram of an example electrical device 900 that may include one or more substrate packages comprise a glass core with the through-glass vias disclosed herein. For example, any suitable ones of the components of the electrical device 900 may include one or more of the integrated circuit device assemblies 800, integrated circuit components 820, integrated circuit devices 700, or integrated circuit dies 602 disclosed herein, and may be arranged in any of the microelectronic assemblies, integrated circuit component packages, or integrated circuit component substrates disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include an other output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include an other input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus, comprising a plurality of dielectric layers, individual of the dielectric layers positioned adjacent to another dielectric layer, individual of the dielectric layers comprising one or more conductive traces and one or more vias; a plurality of conductive contacts located on a top dielectric layer of the dielectric layers; and a glass core positioned adjacent to a bottom dielectric layer of the dielectric layers, the glass core comprising a layer of glass comprising a top surface, a bottom surface opposite the top surface, and a hole extending from the top surface to the bottom surface; and a through-glass via comprising fill material that at least partially fills the hole, a pad, and a metal layer, the through-glass via extending through the hole, a portion of the pad located on the top surface of the layer of glass, a first portion of the metal layer positioned adjacent to an inner wall of the hole, a second portion of the metal layer extending past the top surface of the layer of glass and into the pad, the fill material comprising a first metal, the metal layer comprising a second metal.

Example 2 includes the subject matter of Example 1, wherein the pad comprises a protrusion extending away from the top surface of the layer of glass, the protrusion coaxial with the hole.

Example 3 includes the subject matter of Example 1 or 2, wherein a thickness of the protrusion is in a range of 1-20 microns.

Example 4 includes the subject matter of any one of Examples 1-3, wherein the protrusion is dome-shaped.

Example 5 includes the subject matter of any one of Examples 1-4, wherein the pad does not have a recess.

Example 6 includes the subject matter of any one of Examples 1-5, wherein the second metal is titanium.

Example 7 includes the subject matter of any one of Examples 1-5, wherein the second metal is ruthenium.

Example 8 includes the subject matter of any one of Examples 1-7, wherein the first portion of the metal layer is positioned between the fill material and the layer of glass.

Example 9 includes the subject matter of any one of Examples 1-8, wherein a thickness of the metal layer is less than one micron.

Example 10 includes the subject matter of any one of Examples 1-8, wherein a thickness of the metal layer is less than 500 nanometers.

Example 11 includes the subject matter of any one of Examples 1-8, wherein the second portion of the metal layer extends into the pad by a distance of in a range of 1-20 microns.

Example 12 includes the subject matter of any one of Examples 1-11, wherein the metal layer is a first metal layer, the through-glass via further comprising a second metal layer located on the top surface of the layer of glass and positioned between the top surface of the layer of glass and the pad, the second metal layer comprising a third metal.

Example 13 includes the subject matter of any one of Examples 1-12, and wherein the third metal is titanium.

Example 14 includes the subject matter of any one of Examples 1-13, and wherein the third metal is ruthenium.

Example 15 includes the subject matter of any one of Examples 1-14, wherein the pad is a first pad, the through-glass via further comprising a second pad located on the bottom surface of the layer of glass, the first metal layer further comprising a third portion that extends past the bottom surface of the layer of glass layer and into the second pad.

Example 16 includes the subject matter of any one of Examples 1-14, wherein the fill material is copper.

Example 17 includes the subject matter of any one of Examples 1-14, wherein the fill material is liquid metal.

Example 18 includes the subject matter of any one of Examples 1-17, and wherein the liquid metal comprises gallium, tin, or indium.

Example 19 includes the subject matter of any one of Examples 1-18, wherein the through-glass via is a first through-glass via, the hole is a first hole, the glass core further comprising a second through-glass via extending from the top surface of the layer of glass to the bottom surface of the layer of glass, the top surface of the layer of glass being dished between the first through-glass via and the second through-glass via.

Example 20 includes the subject matter of any one of Examples 1-18, wherein the through-glass via is a first through-glass via, the hole is a first hole, the glass core further comprising a second through-glass via extending from the top surface of the layer of glass to the bottom surface of the layer of glass, the top surface of the layer of glass being scalloped between the first through-glass via and the second through-glass via.

Example 21 includes the subject matter of any one of Examples 1-20, further comprising one or more integrated circuit dies, individual of the integrated circuit dies attached to one or more of the conductive contacts.

Example 22 includes the subject matter of any one of Examples 1-21, and further including a housing, the housing containing the glass core and the integrated circuit dies.

Example 23 includes the subject matter of any one of Examples 1-22, wherein the dielectric layers are first dielectric layers, the conductive traces are first conductive traces, the vias are first vias, and the conductive contacts are first conductive contacts, the apparatus further comprising a plurality of second dielectric layers, individual second dielectric layers positioned adjacent to another second dielectric layer, individual of the second dielectric layers comprising one or more second conductive traces and one or more second vias; and a plurality of second conductive contacts located on a bottom dielectric layer of the second dielectric layers, the glass core positioned between the first dielectric layers and the second dielectric layers.

Example 24 includes the subject matter of any one of Examples 1-23, and further including an electrically conductive path from one of the first conductive contacts to one of the second conductive contacts, the electrically conductive path comprising at least one first conductive trace, at least one first via, the through-glass via, at least one second conductive trace, and at least one second via.

Example 25 includes the subject matter of any one of Examples 1-24, wherein the glass comprises aluminum, oxygen, boron, silicon, and an alkaline-earth metal.

Example 26 includes the subject matter of any one of Examples 1-24, wherein the glass comprises silicon, lithium, oxygen, and a glass layer metal.

Example 27 includes the subject matter of any one of Examples 1-26, and wherein the glass layer metal is gold or silver.

Example 28 includes the subject matter of any one of Examples 23-27 further comprising a printed circuit board, the plurality of second conductive contacts attached to the printed circuit board.

Example 29 is a method comprising forming a hole that extends through a layer of glass; forming a metal layer positioned adjacent to an inner wall of the hole; filling the hole with a fill material, the metal layer positioned between the layer of glass and the fill material, the fill material comprising a metal; etching the fill material to remove a portion of the fill material in the hole, wherein a surface of fill material in the hole is recessed relative to a surface of the layer of glass after etching the fill material; etching the layer of glass, wherein the surface of the layer of glass is recessed relative to the surface of the fill material after etching the layer of glass, a stub of the fill material extending from the surface of the layer of glass after etching the layer of glass; and forming a patterned layer of fill material located on top of the stub and a portion of the surface of the layer of glass, wherein a first portion of the metal layer is positioned adjacent to the inner wall of the hole, a second portion of the metal layer extends past the surface of the layer of glass and into the patterned layer of fill material.

Example 30 includes the subject matter of Example 29, and wherein the metal layer is a first metal layer, the method further comprising, after etching the layer of glass and prior to forming the patterned layer of fill material, forming a second metal layer on the surface of the layer of glass.

Example 31 includes the subject matter of any one of Examples 29 and 30, and wherein the patterned layer of fill material comprises a protrusion that extends away from the surface of the glass, the protrusion coaxial with the hole.

Example 32 includes the subject matter of any one of Examples 29-31, and wherein the protrusion is dome-shaped.

Example 33 includes the subject matter of any one of Examples 29-32, wherein the patterned layer of fill material does not have a recess.

Example 34 includes the subject matter of any one of Examples 29-33, and wherein the metal layer comprises titanium.

Example 35 includes the subject matter of any one of Examples 29-34, and wherein the metal layer comprises ruthenium.

Example 36 includes the subject matter of any one of Examples 29-35, wherein the fill material comprises copper.

Example 37 includes the subject matter of any one of Examples 29-35, wherein the fill material is liquid metal.

Example 38 includes the subject matter of any one of Examples 37, wherein the liquid metal comprises gallium, tin, or indium.

Example 39 includes the subject matter of any one of Examples 29-38, wherein the glass comprises aluminum, oxygen, boron, silicon, and an alkaline-earth metal.

Example 40 includes the subject matter of any one of Examples 29-38, wherein the glass comprises silicon, lithium, oxygen, and a glass layer metal.

Example 41 includes the subject matter of any one of Examples 29-40, and wherein the glass layer metal is gold or silver.

Example 42 includes the subject matter of any one of Examples 29-41, and wherein a thickness of the protrusion is in a range of 1-20 microns.

Example 43 includes the subject matter of any one of Examples 29-42, wherein a thickness of the metal layer is less than 500 nanometers.

Example 44 includes the subject matter of any one of Examples 29-43, wherein the second portion of the metal layer extends into the patterned layer of fill material by a distance in a range of 1-20 microns.

1. An apparatus, comprising:
a plurality of dielectric layers, individual of the dielectric layers positioned adjacent to another dielectric layer, individual of the dielectric layers comprising one or more conductive traces and one or more vias;
a plurality of conductive contacts located on a top dielectric layer of the dielectric layers; and
a glass core positioned adjacent to a bottom dielectric layer of the dielectric layers, the glass core comprising:
a layer of glass comprising a top surface, a bottom surface opposite the top surface, and a hole extending from the top surface to the bottom surface; and
a through-glass via comprising fill material that at least partially fills the hole, a pad, and a metal layer, the through-glass via extending through the hole, a portion of the pad located on the top surface of the layer of glass, a first portion of the metal layer positioned adjacent to an inner wall of the hole, a second portion of the metal layer extending past the top surface of the layer of glass and into the pad, the fill material comprising a first metal, the metal layer comprising a second metal.

2. The apparatus of claim 1, wherein the pad comprises a protrusion extending away from the top surface of the layer of glass, the protrusion coaxial with the hole.

3. The apparatus of claim 2, wherein a thickness of the protrusion is in a range of 1-20 microns.

4. The apparatus of claim 1, wherein the pad does not have a recess.

5. The apparatus of claim 1, wherein the second metal is titanium or ruthenium.

6. The apparatus of claim 1, wherein the first portion of the metal layer is positioned between the fill material and the layer of glass.

7. The apparatus of claim 1, wherein the second portion of the metal layer extends into the pad by a distance in a range of 1-20 microns.

8. The apparatus of claim 1, wherein the metal layer is a first metal layer, the through-glass via further comprising a second metal layer located on the top surface of the layer of glass and positioned between the top surface of the layer of glass and the pad, the second metal layer comprising a third metal.

9. The apparatus of claim 1, wherein the pad is a first pad, the through-glass via further comprising a second pad located on the bottom surface of the layer of glass, the metal layer further comprising a third portion that extends past the bottom surface of the layer of glass layer and into the second pad.

10. The apparatus of claim 1, wherein the fill material is copper.

11. The apparatus of claim 1, wherein the fill material is liquid metal.

12. The apparatus of claim 1, wherein the through-glass via is a first through-glass via, the hole is a first hole, the glass core further comprising a second through-glass via extending from the top surface of the layer of glass to the bottom surface of the layer of glass, the top surface of the layer of glass being dished between the first through-glass via and the second through-glass via.

13. The apparatus of claim 1, wherein the through-glass via is a first through-glass via, the hole is a first hole, the glass core further comprising a second through-glass via extending from the top surface of the layer of glass to the bottom surface of the layer of glass, the top surface of the layer of glass being scalloped between the first through-glass via and the second through-glass via.

14. The apparatus of claim 1, further comprising one or more integrated circuit dies, individual of the integrated circuit dies attached to one or more of the conductive contacts.

15. The apparatus of claim 1, wherein the dielectric layers are first dielectric layers, the conductive traces are first conductive traces, the vias are first vias, and the conductive contacts are first conductive contacts, the apparatus further comprising:
a plurality of second dielectric layers, individual second dielectric layers positioned adjacent to another second dielectric layer, individual of the second dielectric layers comprising one or more second conductive traces and one or more second vias; and
a plurality of second conductive contacts located on a bottom dielectric layer of the second dielectric layers, the glass core positioned between the first dielectric layers and the second dielectric layers.

16. The apparatus of claim 15, further comprising an electrically conductive path from one of the first conductive contacts to one of the second conductive contacts, the electrically conductive path comprising at least one first conductive trace, at least one first via, the through-glass via, at least one second conductive trace, and at least one second via.

17. The apparatus of claim 15, further comprising a printed circuit board, the plurality of second conductive contacts attached to the printed circuit board.

18. The apparatus of claim 1, wherein the glass comprises aluminum, oxygen, boron, silicon, and an alkaline-earth metal.

19. A method comprising:
forming a hole that extends through a layer of glass;
forming a metal layer positioned adjacent to an inner wall of the hole;
at least partially filling the hole with a fill material, the metal layer positioned between the layer of glass and the fill material, the fill material comprising a metal;
etching the fill material to remove a portion of the fill material in the hole, wherein a surface of fill material in the hole is recessed relative to a surface of the layer of glass after etching the fill material;
etching the layer of glass, wherein the surface of the layer of glass is recessed relative to the surface of the fill material after etching the layer of glass, a stub of the fill material extending from the surface of the layer of glass after etching the layer of glass; and
forming a patterned layer of fill material located on top of the stub and a portion of the surface of the layer of glass, wherein a first portion of the metal layer is positioned adjacent to the inner wall of the hole, a second portion of the metal layer extends past the surface of the layer of glass and into the patterned layer of fill material.

20. The method of claim 19, wherein the metal layer is a first metal layer, the method further comprising, after etching the layer of glass and prior to forming the patterned layer of fill material, forming a second metal layer on the surface of the layer of glass.

21. The method of claim 19, wherein the patterned layer of fill material comprises a protrusion that extends away from the surface of the glass, the protrusion coaxial with the hole.

22. The method of claim 19, wherein the patterned layer of fill material does not have a recess.

23. The method of claim 22, wherein the metal layer comprises titanium or ruthenium.

24. The method of claim 19, wherein the fill material comprises copper.

25. The method of claim 19, wherein the second portion of the metal layer extends into the patterned layer of fill material by a distance in a range of 1-20 microns.
